(19) United States
(12) Patent Application Publication
(10) Pub. No.: US 2006/0063379 A1
(43) Pub. Date: Mar. 23, 2006

(54) Forming a combined copper diffusion barrier and seed layer

(76) Inventors: Thomas S. Dory, Gilbert, AZ (US); Steven W. Johnston, Portland, OR (US)

Correspondence Address: TROP PRUNER & HU, PC, 8554 KATY FREEWAY, SUITE 100, HOUSTON, TX, 77024, US

(21) Appl. No.: 10/943,359

(22) Filed: Sep. 17, 2004

(51) Int. Cl. H01L 21/4763

(52) U.S. Cl. 438/643

(57) ABSTRACT

Noble metal may be used as both a diffusion barrier and seed layer to prevent diffusion from copper lines electroplated using the noble metal layer as a seed layer. The barrier and seed layer and the copper layer may be formed in a high aspect ratio trench in one embodiment.

### BACKGROUND

This invention relates generally to processes for making semiconductor integrated circuits.

In the so called damascene approach, copper layers may be formed in trenches within interlayer dielectric material. In some cases, the copper material ultimately forms metal lines for power and/or signal conduction. However, copper material may tend to diffuse causing adverse effects on nearby components.

Thus, it is desirable to provide a diffusion barrier to prevent the diffusion of copper atoms. Currently, tantalum or titanium based diffusion barriers are used. However, tantalum and titanium form native oxides which hinder direct electroplating of the copper onto the tantalum or titanium surface with acceptable adhesion and within-wafer uniformity.

Thus, it may be necessary to form a copper seed deposition in situ (without a vacuum break). However, the need to provide a physical vapor deposition copper seed layer is cumbersome. Moreover, the adhesion between the overlying barrier material and the underlying dielectric may be unacceptable in some cases.

Thus, there is a need for better ways to provide diffusion barriers under copper layers.

### BRIEF DESCRIPTION OF THE DRAWINGS

FIG. 1 is an enlarged cross-sectional view of a portion of a wafer in accordance with one embodiment of the present invention;

FIG. 2 is an enlarged cross-sectional view of the wafer after further processing in accordance with one embodiment of the present invention;

FIG. 3 is an enlarged cross-sectional view of the wafer after further processing in accordance with one embodiment of the present invention;

FIG. 4 is an enlarged cross-sectional view of the wafer after further processing in accordance with one embodiment of the present invention;

FIG. 5 is an enlarged cross-sectional view of the wafer after further processing in accordance with another embodiment of the present invention; and

FIG. 6 is an enlarged cross-sectional view of the wafer after further processing in accordance with one embodiment of the present invention.

### DETAILED DESCRIPTION

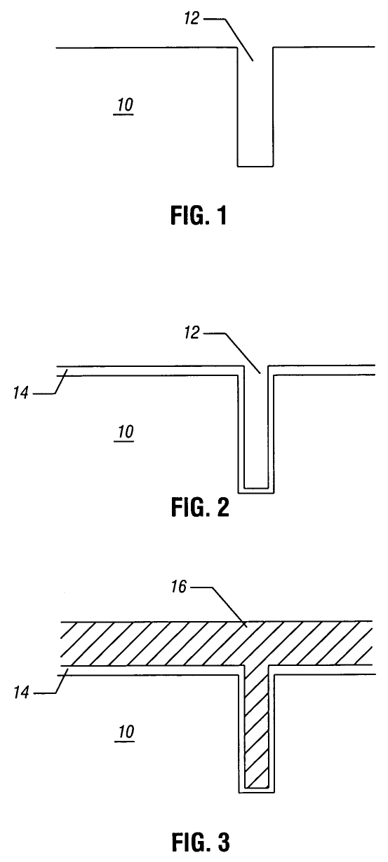

Referring to FIG. 1, a semiconductor substrate 10 may have a via 12 formed therein. In one embodiment, the via 12 may have a high aspect ratio (e.g., 3 to 1) and may be formed by deep reactive ion etching (DRIE), for example. Alternatively, conventional lithography and etching may be used to form a via 12. The via 12 may be defined according to the damascene approach in one embodiment. While embodiments are illustrated that use the via first process, other processes may involve a via first process or other techniques.

Following an in situ degas and/or preclean, a combined diffusion barrier and seed layer 14 may be deposited, as shown in FIG. 2, in one embodiment. The layer 14 acts as a seed layer for electroplating or electroless plating the subsequently applied overlying copper (or other metal) layer. The layer 14 also acts as a diffusion barrier to prevent diffusion of copper into the substrate 10.

The layer 14 may be formed of suitable noble metals (including their nitrides and carbides) such as platinum, gold, palladium, osmium, ruthenium, rhodium, molybdenum, iridium, RuN, RuO, and MoN, to mention several examples. In one embodiment, the layer 14 may have a thickness of between 7.5 nm and 60 nm and, most advantageously, about 40 nm. The layer 14 may be formed of physical vapor deposition including sputtering or atomic layer deposition, chemical vapor deposition or hydrid atomic layer deposition and chemical vapor deposition.

As shown in FIG. 3, a trench plus via fill may be accomplished, filling the entire structure with copper 16. In some embodiments a dual damascene plating process may be used. This may be done using electroplating or other fill techniques.

In some embodiments of the present invention, oxidation of the diffusion barrier and seed layer 14 is reduced by using a noble metal. This may be accomplished without the need to provide a separate, additional in situ seed layer. The noble metal layer 14 is conductive enough to enable direct plating on the barrier without the need for a separate copper seed in some embodiments. The unoxidized noble metal diffusion barrier and seed layer 14 may promote adhesion between the plated copper and the underlying material without the use of an intermediate adhesion layer and may reduce the need to remove a native metal oxide layer from the barrier in the copper plating tool in some applications.

By using a single barrier material process, tool throughput may be increased and integration concerns may be reduced in some embodiments. In addition, the need to first etch a barrier material, prior to copper plating, to improve adhesion, may be reduced in some embodiments. Also, the need to chemically activate the barrier surface may be reduced in some embodiments, thereby saving process steps, lowering process cost, and alleviating reclamation and/or environmental concerns.

The deposition of noble metals using physical vapor deposition, chemical vapor deposition, and atomic layer deposition is well known. For example the deposition of ruthenium is described in Y. Matsui et al., Electro. And Solid-State Letters, 5, C18 (2002) using Ru(EtCp)2. The use of [RuC5H5(CO)2]2,3 to deposit ruthenium is described in K. C. Smith et al., Thin Solid Films, v 376, p. 73 (November 2000). The use of Ru-tetramethylhentane dionate and Ru(CO)₆ to deposit ruthenium is described in http://thinfilm.snu.ac.kr/research/electrode.htm. The deposition of rhodium is described in A. Etspuler and H. Suhr, Appl. Phys. A, vA 48, p. 373 (1989) using dicarbonyl (2,4-pentanedionato)rhodium(I).

The deposition of molybdenum is described in K. A. Gesheva and V. Abrosimova, Bulg. J. of Phys., v 19, p. 78 (1992) using Mo(Co)₆. The deposition of molybdenum using MoF6 is described in D. W. Woodruff and R. A. Sanchez-Martinez, Proc. of the 1986 Workshop of the Mater. Res. Soc., p. 207 (1987). The deposition of osmium is described in Y. Senzaki et al., Proc. of the 14^{th} Inter. Conf. And EUROCVD-11, p. 933 (1997) using Os(hexafluoro-2-butyne)(CO)4. The deposition of palladium is described in V. Bhaskaran, Chem. Vap. Dep., v 3, p. 85 (1997) using 1,1,1,5,5,5-hexafluoro-2,4-pentanedionato palladium(II) and in E. Feurer and H. Suhr, Tin Solid Films, v 157, p. 81 (1988) using allylcyclopentadienyl palladium complex.

The deposition of platinum is described in M. J. Rand, J. Electro. Soc., v 122, p. 811 (1975) and J. M. Morabito and M. J. Rand, Thin Solid Films, v 22, p. 293 (1974) using Pt(PF3)4) and in the Journal of the Korean Physical Society, Vol. 33, November 1998, pp. S148-S151 using ((MeCp)PtMe₃) and in Z. Xue, H. Thridandam, H. D. Kaesz, and R. F. Hicks, Chem. Mater. 1992, 4, 162 using ((MeCp)PtMe₃).

The deposition of gold is described in H. Uchida et al., Gas Phase and Surf. Chem. of Electro. Mater. Proc. Symp., p. 293 (1994) and H. Sugawara et al., Nucl. Instrum. and Methods in Physics Res., Section A, v 228, p. 549 (1985) using dimethyl(1,1,1,5,5,5-hexafluoroaminopenten-2-onato)Au(III). The deposition of iridium has been described using (Cyclooctadiene)Iridium(hexafluoro-acetylacetonate). Noble metals may be plated directly on tantalum nitride using two-step plating processes involving a basic electroplating bath copper seed plating followed by acidic electroplating bath copper bulk plating.

In accordance with one embodiment of the present invention, a ruthenium plating solution may include ruthenium (III) at 1 to 10 grams per liter, ethylene diamine tetraacetic acid at 20 to 100 grams per liter, potassium hydroxide at 100 to 200 grams per liter, dimethyl amine borane (DMAB) at 1 to 10 grams per liter, at 15 to 60° C. and a pH of about 10 to about 13.

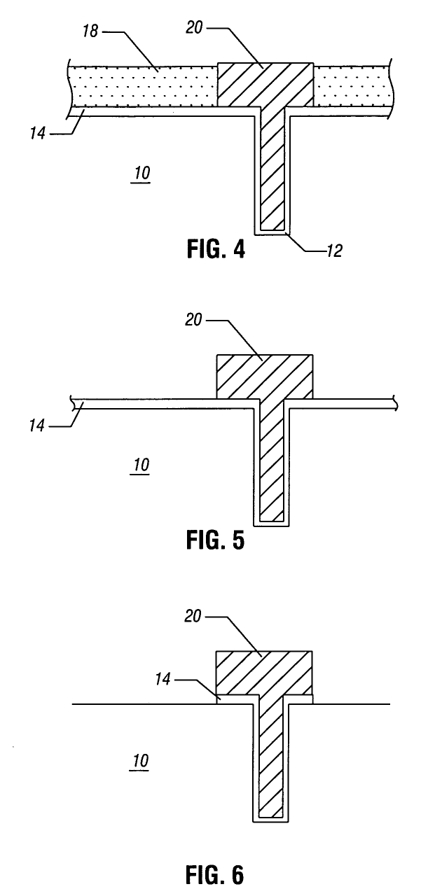

Referring to FIG. 4, in accordance with another embodiment of the present invention, after forming the via 12 in the substrate 10, and applying the layer 14 as described previously, a photoresist layer 18 may be deposited and patterned to have an opening over the via 12. Then, the copper plating 20 may form a via and an overlying bump.

Thereafter, as shown in FIG. 5, the photoresist may be stripped. Then, as shown in FIG. 6, the exposed portion of the layer 14 may be removed by a wet or dry etch process. Thus, the vias and the traces may be formed in one process step.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a noble metal diffusion barrier and seed layer on a semiconductor substrate; and
plating a metal layer on said diffusion barrier and seed layer.

2. The method of claim 1 including depositing said noble metal using physical vapor deposition.

3. The method of claim 1 including depositing said noble metal using sputtering.

4. The method of claim 1 including forming said diffusion barrier and seed layer to a thickness of less than 60 nm.

5. The method of claim 4 including forming said diffusion barrier and seed layer of a thickness of about 40 nm.

6. The method of claim 1 including forming a via trench, coating said trench with said diffusion barrier and seed layer and filling said trench with said metal layer.

7. The method of claim 1 including patterning a mask layer over said diffusion barrier and seed layer and electroplating a copper metal layer using said mask layer.

8. The method of claim 7 including stripping said mask layer.

9. The method of claim 8 including removing a portion of said diffusion barrier and seed layer not covered by said copper layer.

10. A semiconductor structure comprising:
a substrate;
a noble metal diffusion barrier and seed layer over said substrate; and
a copper layer plated on said diffusion barrier and seed layer.

11. The structure of claim 10 wherein said noble metal is selected from the group including platinum, gold, palladium, osmium, ruthenium, rhodium, molybdenum, iridium, and nitrides and carbides thereof.

12. The structure of claim 10 wherein said diffusion barrier and seed layer is less than 60 nm thick.

13. The structure of claim 10 wherein said diffusion barrier and seed layer is about 40 nm thick.

14. The structure of claim 10 including a via formed of said copper layer.

15. The structure of claim 10 wherein said copper layer forms a via in a trench.

16. A method comprising:
electroplating a copper layer directly onto a noble metal layer.

17. The method of claim 16 including forming said noble metal layer using a ruthenium.

18. The method of claim 16 including forming said noble metal layer of a thickness of less than 60 nm.

19. The method of claim 16 including forming said noble metal layer of a thickness of about 40 nm.

20. The method of claim 16 including forming said noble metal layer directly on a semiconductor substrate.
